(19) United States
(12) Patent Application Publication
(10) Pub. No.: US 2025/0022778 A1
(43) Pub. Date: Jan. 16, 2025

(54) SEMICONDUCTOR MODULE

(71) Applicant: FUJI ELECTRIC CO., LTD., Kawasaki-shi (JP)

(72) Inventor: Eri KAMEDA, Matsumoto-city (JP)

(73) Assignee: FUJI ELECTRIC CO., LTD., Kawasaki-shi (JP)

(21) Appl. No.: 18/900,387

(22) Filed: Sep. 27, 2024

Related U.S. Application Data
(63) Continuation of application No. PCT/JP2023/032471, filed on Sep. 6, 2023.

(30) Foreign Application Priority Data
Oct. 13, 2022 (JP) 2022-164663

(51) Int. Cl. H01L 23/495; H01L 23/043; H01L 25/10

(52) U.S. Cl. CPC H01L 23/49537; H01L 23/043; H01L 23/49558; H01L 25/105

(57) ABSTRACT

A semiconductor module, including: a semiconductor unit including first and second switching elements; a terminal structure including: a positive terminal electrically connected to a positive electrode of the first switching element, a negative terminal electrically connected to a negative electrode of the second switching element, a first insulating member sandwiched between the positive terminal and the negative terminal, and includes a protruding portion where a part of the first insulating member protrudes from between the positive terminal and the negative terminal, and second and third insulating members sandwiching the terminal structure and covering front and rear surfaces of at least a part of the protruding portion; and a case that is integrally molded with the terminal structure, and that houses the semiconductor unit.

### CROSS-REFERENCE TO RELATED APPLICATION

This application is a continuation application of International Application PCT/JP2023/032471 filed on Sep. 6, 2023, which designated the U.S., which claims priority to Japanese Patent Application No. 2022-164663, filed on Oct. 13, 2022, the entire contents of which are incorporated herein by reference.

### BACKGROUND OF THE INVENTION

### 1. Field of the Invention

The embodiments discussed herein relate to a semiconductor module including a switching element.

### 2. Background of the Related Art

A semiconductor module including a switching element such as an insulated gate bipolar transistor (IGBT) or a power metal-oxide-semiconductor field-effect transistor (MOSFET) is used in a power converter apparatus that uses a high voltage and a large current.

To reduce the inductance of a semiconductor module, some modules are constructed so that the positive terminal and the negative terminal (or a wire connected to the positive terminal and a wire connected to the negative terminal) are placed in close proximity with an insulating material, such as insulating paper, in between.

Examples of such a structure are disclosed in paragraph [0096] of Japanese Laid-open Patent Publication No. 2020-009834, paragraph [0021] of Japanese Laid-open Patent Publication No. 2016-066974,paragraph [0046] and FIG. 4(a) of Japanese Laid-open Patent Publication No. 2013-009501, paragraph [0019] and FIG. 1(a) of Japanese Laid-open Patent Publication No. 2006-086438, paragraph [0012] and FIG. 1 of International Publication Pamphlet No. WO 2022/091288,paragraph [0018] and FIG. 5 of Japanese Laid-open Patent Publication No. 2021-106235 and Japanese Laid-open Patent Publication No. 2022-006876, paragraph [0033] and FIG. 1 of International Publication Pamphlet No. WO 2019/098368, paragraph [0018] and FIG. 2 of Japanese Laid-open Patent Publication No. 2016-006834, paragraph [0162] and FIG. 36(A) of Japanese Laid-open Patent Publication No. 2009-081993 and Japanese Laid-open Patent Publication No. 2008-029117, paragraph [0023] and FIG. 9 of Japanese Laid-open Patent Publication No. 2010-157565, and paragraph [0054] and FIG. 34 of International Publication Pamphlet No. WO 2020/035931.

To provide a sufficient insulation distance between the positive and negative terminals and prevent dielectric breakdown, the width of the insulating member sandwiched between the positive terminal and the negative terminal may be made wider than the widths of the positive terminal and the negative terminal. In this case, the insulating member will have a protruding portion that protrudes from between the positive and negative terminals.

When a terminal structure where an insulating member with a protruding portion is sandwiched between the positive terminal and the negative terminal is integrally molded with the case of a semiconductor module, the protruding portion may become deformed. Example forms of deformation include bending or curling of the protruding portion due to the influence of resin pressure or the like. Such deformation may prevent sufficient insulation distance from being provided between the positive terminal and the negative terminal, resulting in deterioration in insulation performance.

When a thin material such as insulating paper is used as the insulating material described above, the insulating material is more likely to deform, and fixing the terminal structure to the mold during integral molding may be time-consuming.

### SUMMARY OF THE INVENTION

According to an aspect, there is provided a semiconductor module, including: a semiconductor unit including a first switching element and a second switching element respectively in an upper arm and a lower arm of the semiconductor unit; a terminal structure including a positive terminal that is electrically connected to a positive electrode of the first switching element, a negative terminal that is electrically connected to a negative electrode of the second switching element, a first insulating member that is sandwiched between the positive terminal and the negative terminal and includes a protruding portion where a part of the first insulating member protrudes from between the positive terminal and the negative terminal, and a second insulating member and a third insulating member that sandwich the terminal structure from above and below and cover a front surface and a rear surface of at least a part of the protruding portion; and a case that is integrally molded with the terminal structure which is sandwiched between the second insulating member and the third insulating member, and that houses the semiconductor unit.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a perspective view depicting one example of a semiconductor module according to a first embodiment;

FIG. 2 depicts one example of an equivalent circuit of the semiconductor module according to the first embodiment;

FIG. 3 is a perspective view depicting one example of a terminal structure;

FIG. 4 is a perspective view depicting an example of a terminal structure that is sandwiched between a second insulating member and a third insulating member;

FIG. 5 is a perspective view of an example of a second insulating member;

FIG. 6 depicts an example arrangement of a positive terminal on the second insulating member;

FIG. 7 depicts an example arrangement of the first insulating member on the second insulating member;

FIG. 8 depicts an example arrangement of a negative terminal;

FIG. 9 is a perspective view depicting one example of a third insulating member;

FIG. 10 is a perspective view depicting one example of a rear surface of the third insulating member;

FIG. 11 is a perspective view depicting a modification to a second insulating member;

FIG. 12 is a perspective view depicting a modification to a positive terminal;

FIG. 13 depicts an example arrangement of a positive terminal on the second insulating member according to a modification;

FIG. 14 depicts an example arrangement of the first insulating member on the second insulating member according to a modification;

FIG. 15 is a perspective view depicting a modification to a negative terminal;

FIG. 16 depicts an example arrangement of the negative terminal when using the second insulating member according to a modification;

FIG. 17 depicts an example arrangement of a third insulating member when using the second insulating member according to this modification;

FIG. 18 is a perspective view depicting an example of a semiconductor module according to a second embodiment; and

FIG. 19 is a perspective view depicting an example of a terminal structure sandwiched between a second insulating member and a third insulating member.

### DETAILED DESCRIPTION OF THE INVENTION

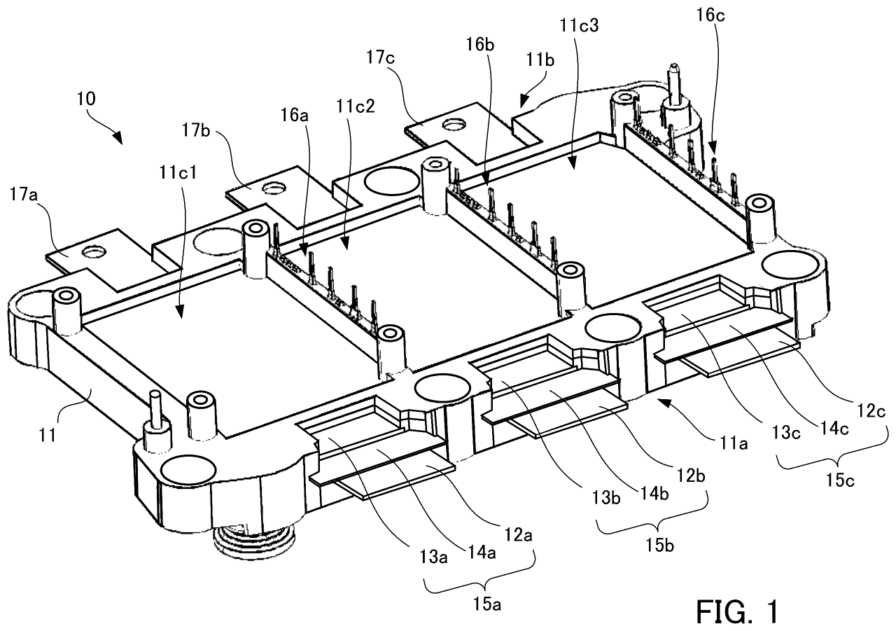

Several embodiments will be described below with reference to the accompanying drawings. Note that in the following description, the expressions “front surface” and “upper surface” refer to a surface of a semiconductor module 10 in FIG. 1 that faces upward. In the same way, the expression “up” refers to the upward direction for the semiconductor module 10 in FIG. 1. The expressions “rear surface” and “lower surface” refer to a surface that faces downward for the semiconductor module 10 in FIG. 1. In the same way, the expression “down” refers to the downward direction for the semiconductor module 10 in FIG. 1. These expressions are used as needed to refer to the same directions in the other drawings. The expressions “front surface”, “upper surface”, “up”, “rear surface”, “lower surface”, “down”, and “side surface” are merely convenient expressions used to specify relative positional relationships and are not intended to limit the technical scope of the present disclosure. As one example, “up” and “down” do not necessarily mean directions that are perpendicular to the ground. That is, the “up” and “down” directions are not limited to the direction of gravity.

### First Embodiment

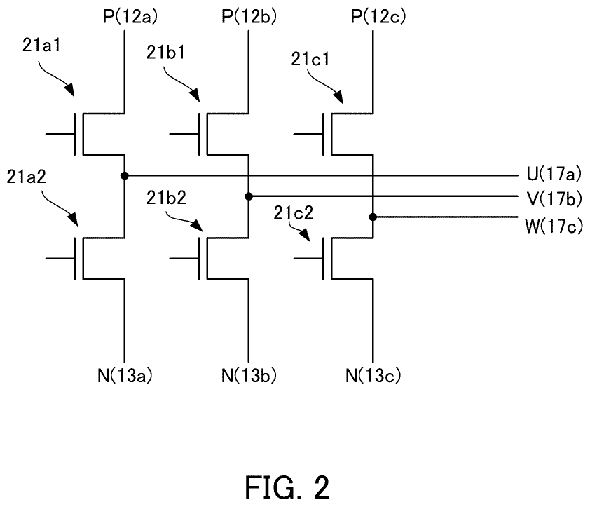

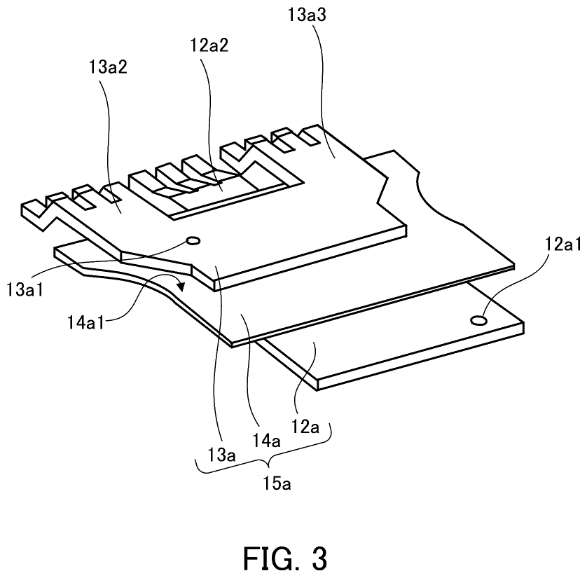

FIG. 1 is a perspective view depicting one example of a semiconductor module according to a first embodiment. FIG. 2 depicts one example of an equivalent circuit of the semiconductor module according to the first embodiment. FIG. 3 is a perspective view depicting one example of a terminal structure.

The semiconductor module 10 includes three semiconductor units (not illustrated) and a case 11 that houses these semiconductor units. Each semiconductor unit includes a ceramic circuit board and a semiconductor chip provided on the ceramic circuit board. Each ceramic circuit board includes an insulating plate, a heat-dissipating plate formed on a rear surface of the insulating plate, and a circuit pattern formed on a front surface of the insulating plate. The insulating plate is made of a ceramic with superior thermal conductivity. Such ceramics include aluminum oxide with high thermal conductivity, aluminum nitride, and silicon nitride. The heat-dissipating plate is made of a metal with superior thermal conductivity. Such metals include aluminum, iron, silver, and copper, as well as alloys containing at least one of these metals. The circuit pattern is made of a metal with superior electrical conductivity. Such metals include copper and copper alloy. Note that the number and shape of the circuit patterns are selected as appropriate according to the specification and the like of the semiconductor module 10. As examples, a direct copper bonding (DCB) board or an active metal brazed (AMB) board may be used as a ceramic circuit board with the configuration described above.

The semiconductor chips include switching elements, such as power MOSFETs or IGBTs, which are made of silicon or silicon carbide. As one example, this type of semiconductor chip includes a drain electrode (or “collector electrode”) as a main electrode on the rear surface and a gate electrode and a source electrode (or “emitter electrode”) as main electrodes on the front surface. As needed, the semiconductor chip also includes a freewheeling diode (FWD), such as a Schottky barrier diode (SBD) or a P-intrinsic-N (PiN) diode. This type of semiconductor chip has a cathode electrode as a main electrode on the rear surface and an anode electrode as a main electrode on the front surface. A reverse-conducting (RC)-IGBT, in which the functions of an IGBT and an FWD are combined, may be used as the semiconductor chip. The number and type of such semiconductor chips are selected as appropriate according to the specification of the semiconductor module 10.

The case 11 includes housing regions 11c1, 11c2, and 11c3 that house the semiconductor units described above. The housing regions 11c1, 11c2, and 11c3 are spaces provided in a central portion of the case 11 along the longitudinal direction of the case 11 in plan view. Inside these housing regions 11c1, 11c2, and 11c3, the semiconductor units are electrically connected to various terminals as described below. Such electrical connections use wiring members, such as bonding wires or a lead frame. The wiring members are made of a material with superior electrical conductivity. Example materials include metals such as aluminum and copper, or an alloy containing at least one of these metals.

The case 11 further includes terminal structures 15a, 15b, and 15c. The terminal structure 15a includes a positive terminal 12a, a negative terminal 13a, and a first insulating member 14a that is sandwiched between the positive terminal 12a and the negative terminal 13a. The terminal structure 15b includes a positive terminal 12b, a negative terminal 13b, and a first insulating member 14b that is sandwiched between the positive terminal 12b and the negative terminal 13b. The terminal structure 15c includes a positive terminal 12c, a negative terminal 13c, and a first insulating member 14c that is sandwiched between the positive terminal 12c and the negative terminal 13c.

The positive terminals 12a, 12b, and 12c and the negative terminals 13a, 13b, and 13c are made of a metal with superior electrical conductivity. Examples of such metal include copper and a copper alloy.

As depicted in FIG. 1, one end of the front surface of each of the positive terminals 12a, 12b, and 12c and the negative terminals 13a, 13b, and 13c is exposed to a first side 11a of the case 11 along the longitudinal direction. Note that the positive terminals 12a, 12b, and 12c and the negative terminals 13a, 13b, and 13c are formed as flat plates on at least the first side 11a-side.

The exposed parts of the positive terminals 12a, 12b, and 12c and the negative terminals 13a, 13b, and 13c are connected to wiring that electrically connects as one example capacitors that function as a power source to the semiconductor units. Note that the other ends of the positive terminals 12a, 12b, and 12c and the negative terminals 13a, 13b, and 13c are electrically connected to the semiconductor units inside the case 11.

In the equivalent circuit of FIG. 2, the positive terminals 12a, 12b, and 12c are indicated as “P(12a)”, “P(12b)”, and “P(12c)”, and the negative terminals 13a, 13b, and 13c are indicated as “N(13a)”, “N(13b)”, and “N(13c)”.

The positive terminal 12a of the terminal structure 15a is electrically connected to a positive electrode terminal of a first switching element 21a1 of an upper arm, as depicted in FIG. 2, of a semiconductor unit housed inside the housing region 11c1. The negative terminal 13a of the terminal structure 15a is electrically connected to a negative electrode terminal of a second switching element 21a2 of a lower arm, as depicted in FIG. 2, of the semiconductor unit housed inside the housing region 11c1. As one example, when the first switching element 21a1 and the second switching element 21a2 are IGBTs, the positive terminal is the collector electrode of the first switching element 21a1 and the negative terminal is the emitter electrode of the second switching element 21a2.

In the same way, the positive terminal 12b of the terminal structure 15b is electrically connected to a positive electrode terminal of a first switching element 21b1 of an upper arm, as depicted in FIG. 2, of the semiconductor unit housed inside the housing region 11c2. The negative terminal 13b of the terminal structure 15b is electrically connected to a negative electrode terminal of a second switching element 21b2 of a lower arm, as depicted in FIG. 2, of the semiconductor unit housed inside the housing region 11c2. In the same way, the positive terminal 12c of the terminal structure 15c is electrically connected to a positive electrode terminal of a first switching element 21c1 of an upper arm, as depicted in FIG. 2, of the semiconductor unit housed inside the housing region 11c3. The negative terminal 13c the terminal structure 15c is of electrically connected to a negative electrode terminal of a second switching element 21c2 of a lower arm, as depicted in FIG. 2, of the semiconductor unit housed inside the housing region 11c3.

As one example, the first insulating members 14a, 14b, and 14c are insulating paper. As examples of insulating paper, it is possible to use insulating paper made of wholly aromatic polyamide polymer, or a sheet-shaped insulating paper made of a fluorine-based or polyimide-based resin material. The first insulating members 14a, 14b, and 14c may also be ceramic substrates made of a material, such as aluminum oxide or silicon nitride.

Front ends on the first side 11a-sides of the first insulating members 14a, 14b, and 14c are positioned between the front ends of the positive terminals 12a, 12b, and 12c and the front ends of the negative e terminals 13a, 13b, and 13c. With this configuration, the positive terminals 12a, 12b, and 12c and the negative terminals 13a, 13b, and 13c are kept insulated from each other.

As depicted in FIG. 3, in the terminal structure 15a, the positive terminal 12a and the negative terminal 13a are provided with openings 12a1 and 13a1. The openings 12a1 and 13a1 are holes through which positioning pins, which extend from a mold used during integral molding of the case 11 are passed.

One part 12a2 of the positive terminal 12a extends from a rear surface of the first insulating member 14a toward the inside of the case 11. This part 12a2 is stepped. As one example, a lowest step at a front end of this part 12a2 is connected to the positive electrode of a semiconductor unit via a wiring member, such as a bonding wire or a lead frame.

Above the first insulating member 14a, the negative terminal 13a that extends toward the inside of the case 11 is divided into two parts 13a2 and 13a3. These parts 13a2 and 13a3 extend toward the inside of the case 11 from the front surface of the first insulating member 14a. These parts 13a2 and 13a3 are also stepped. As one example, the lowest steps at the front end of the parts 13a2 and 13a3 are connected to the negative electrode of a semiconductor unit via a wiring member, such as a bonding wire or a lead frame.

To provide a sufficient insulation distance between the positive terminal 12a and the negative terminal 13a and prevent dielectric breakdown, the width of the first insulating member 14a (that is, the length in the longitudinal direction of the case 11) is wider than the widths of the positive terminal 12a and the negative terminal 13a. For this reason, a part of the first insulating member 14a is a protruding portion 14a1 that protrudes from between the positive terminal 12a and the negative terminal 13a.

The terminal structures 15b and 15c have the same configuration as the terminal structure 15a depicted in FIG. 3.

A protruding portion 14a1 as depicted in FIG. 3 may deform when the terminal structure 15a and the case 11 are integrally molded, which causes deterioration in the insulation performance. When a thin material such as insulating paper is used as the first insulating member 14a, the first insulating member 14a is more likely to deform, and fixing the terminal structure 15a to the mold during integral molding may be time consuming.

For this reason, in the semiconductor module 10 according to the first embodiment, each of the terminal structures 15a, 15b, and 15c described above is sandwiched from above and below by a second insulating member and a third insulating member that cover at least part of the front and rear surfaces of the protruding portions described above.

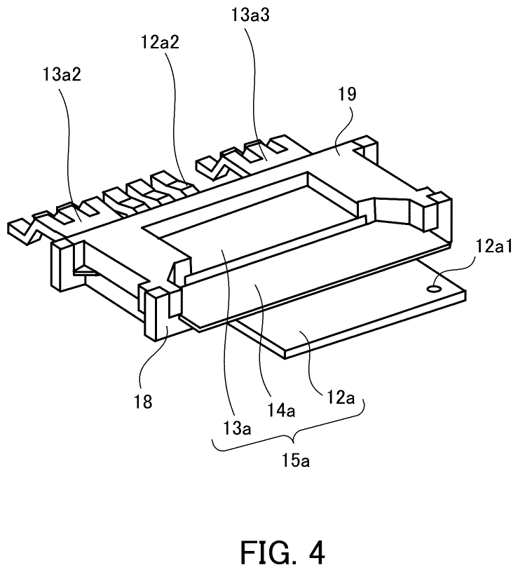

FIG. 4 is a perspective view depicting an example of a terminal structure that is sandwiched between a second insulating member and a third insulating member.

The second insulating member 18 and the third insulating member 19 sandwich the terminal structure 15a from above and below and cover at least the front and rear surfaces of a part of the protruding portion of the first insulating member 14a (as one example, the protruding portion 14a1 in FIG. 3). The terminal structure 15a is integrally molded with the case 11 in this state where the terminal structure 15a is sandwiched between the second insulating member 18 and the third insulating member 19. Although not illustrated, the terminal structures 15b and 15c are integrally molded with the case 11 in a state where the terminal structures 15b and 15c are sandwiched in the same way between a second insulating and member a third insulating member.

With this configuration, it is possible to suppress deformation of the protruding portions of the first: insulating members 14a, 14b, and 14c during molding and thereby prevent deterioration in insulation performance.

In addition, since deformation of the protruding portions of the first insulating members 14a, 14b, and 14c may be suppressed, it is possible to reduce the time taken to fix the terminal structures 15a, 15b, and 15c to a mold during integral molding. Since it is no longer needed to provide pins or the like in the mold for suppressing deformation of the protruding portions of the first insulating members 14a, 14b, and 14c, the structure of the mold is also simplified.

Note that thermoplastic resin is used as the material of the second insulating member 18 and the third insulating member 19 in the same way as the material of the case 11. By doing so, it is possible to prevent resin from flowing into the terminal structure 15a during integral molding.

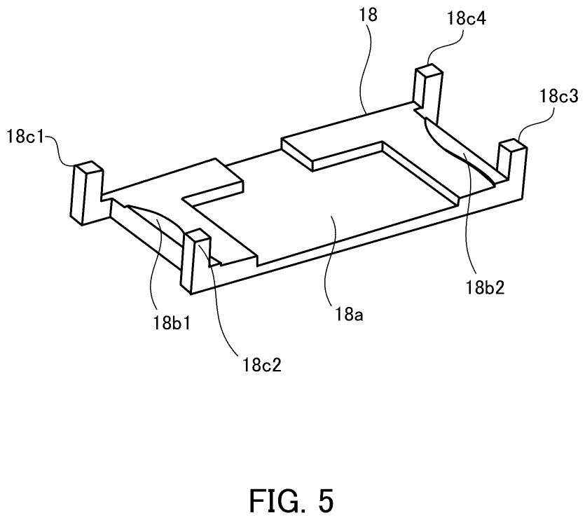

Note that specific example configurations of the second insulating member 18 and the third insulating member 19 will be described later (see FIGS. 5, 9, and 10).

As depicted in FIG. 1, control terminals 16a, 16b, and 16c are also attached to the sides of the housing regions 11c1, 11c2, and 11c3, respectively, of the case 11.

The control terminals 16a, 16b, and 16c are made of metal with superior electrical conductivity. Example metals include copper, copper alloy, aluminum, and aluminum alloy.

The control terminals 16a are electrically connected to the gate terminal of the first switching element 21a1 or the second switching element 21a2 (depicted in FIG. 2) of the semiconductor unit housed in the housing region 11c1. The control terminals 16b are electrically connected to the gate terminal of the first switching element 21b1 or the second switching element 21b2 (depicted in FIG. 2) of the semiconductor unit housed in the housing region 11c2. The control terminals 16c are electrically connected to the gate terminal of the first switching element 21c1 or the second switching element 21c2 (depicted in FIG. 2) of the semiconductor unit housed in the housing region 11c3.

The case 11 further includes a U terminal 17a, a V terminal 17b, and a W terminal 17c.

One end of each of the U terminal 17a, the V terminal 17b, and the W terminal 17c is exposed on a second side 11b of the case 11 along the longitudinal direction of the case 11. The U terminal 17a, the V terminal 17b, and the W terminal 17c are made of a metal with superior electrical conductivity. Example metals include copper and copper alloy. As described below, the other ends of the U terminal 17a, the V terminal 17b, and the W terminal 17c are electrically connected to the semiconductor units inside the case 11.

In the equivalent circuit in FIG. 2, the U terminal 17a, the V terminal 17b, and the W terminal 17c are indicated “U(17a”, “V(17b)”, and “W(17c)”, respectively.

The U terminal 17a is electrically connected to the negative terminal of the first switching element 21a1 and the positive terminal of the second switching element 21a2 (depicted in FIG. 2) of the semiconductor unit housed in the housing region 11c1. The V terminal 17b is electrically connected to the negative terminal of the first switching element 21b1 and the positive terminal of the second switching element 21b2 (depicted in FIG. 2) of the semiconductor unit housed in the housing region 11c2. The W terminal 17c is electrically connected to the negative terminal of the first switching element 21c1 and the positive terminal of the second switching element 21c2 (depicted in FIG. 2) of the semiconductor unit housed in the housing region 11c3.

The case 11 is integrally formed with the terminal structures 15a, 15b, and 15c which are sandwiched between a second insulating member and a third insulating member, the control terminals 16a, 16b, 16c, the U terminal 17a, the V terminal 17b, and the W terminal 17c. As one example, this molding is performed by injection molding using thermoplastic resin. Examples of thermoplastic resin include polyphenylene sulfide (PPS) resin, polybutylene terephthalate (PBT) resin, polybutylene succinate (PBS) resin, polyamide (PA) resin, and acrylonitrile butadiene styrene (ABS) resin.

In addition, semiconductor units are housed in the housing regions 11c1, 11c2, and 11c3, and after the electrical connections have been made with the various terminals mentioned above, the inside of the case 11 is encapsulated with an encapsulating member. The encapsulating member includes a thermosetting resin and a filler contained in the thermosetting resin. Example thermosetting resins include epoxy resin, phenolic resin, and maleimide resin. The filler is silicon oxide, aluminum oxide, boron nitride, or aluminum nitride.

Although the semiconductor module 10 has been described above as including three semiconductor units, the present disclosure is not limited to this. The semiconductor module 10 may include one, two, or four or more semiconductor units.

Next, examples of the second insulating member and the third insulating member that sandwich the terminal structures 15a, 15b, and 15c from above and below will be described in more detail. Note that although examples of the second insulating member and the third insulating member that sandwich the terminal structure 15a from above and below are described below, the second insulating members and the third insulating members that sandwich the terminal structures 15b and 15c from above and below have the same configuration.

FIG. 5 is a perspective view of an example of a second insulating member.

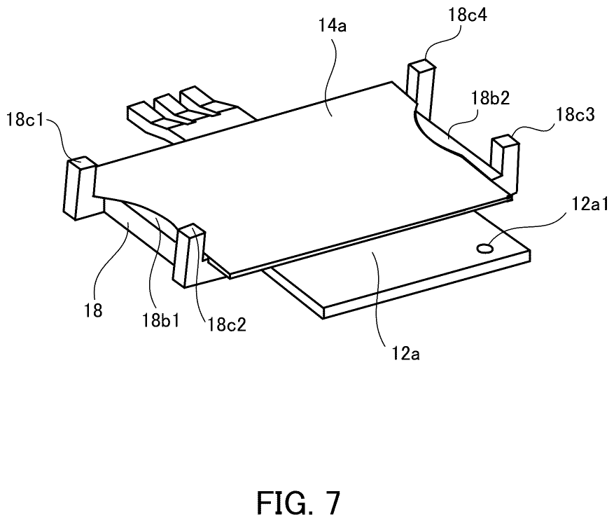

The surface of the second insulating member 18 that faces the terminal structure 15a is provided with a recess 18a into which the positive terminal 12a is fitted. In addition, the surface of the second insulating member 18 that faces the terminal structure 15a is provided with first protruding portions 18b1 and 18b2 that position the first insulating member 14a. The first protruding portions 18b1 and 18b2 are disposed so as to face parts of an outer edge of the first insulating member 14a (see FIG. 7).

Pillars 18c1 and 18c2 are also provided on a first side of the surface of the second insulating member 18 that faces the terminal structure 15a, and pillars 18c3 and 18c4 are provided on a second side at an opposite end to the first side. Note that the number of pillars on each of the first and second sides is not limited to two, and may be one or three or more pillars.

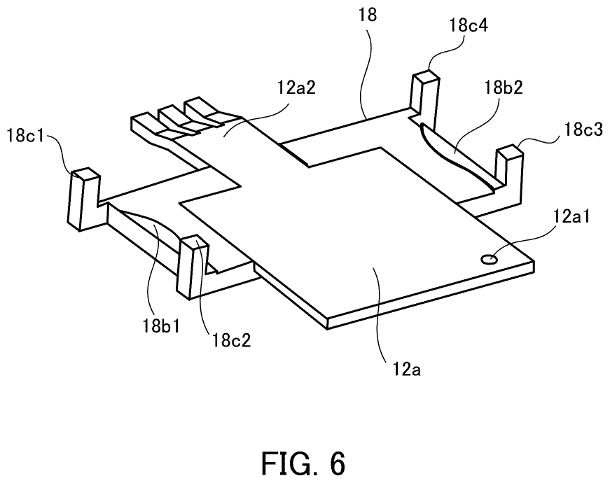

FIG. 6 depicts an example arrangement of a positive terminal on the second insulating member. As depicted in FIG. 6, a part of the positive terminal 12a is fitted into the recess 18a of the second insulating member 18. This prevents the positive terminal 12a from becoming displaced.

FIG. 7 depicts an example arrangement of the first insulating member on the second insulating member. The first insulating member 14a is disposed on a part of the upper surface of the positive terminal 12a that is fitted into the recess 18a of the second insulating member 18. The first protruding portions 18b1 and 18b2 of the second insulating member 18 protrude inward for the first insulating member 14a so as to engage side edges of the first insulating member 14a. Side surfaces of side edges of the first insulating member 14a that face the first protruding portions 18b1 and 18b2 are recessed inward. The first insulating member 14a is positioned by the first protruding portions 18b1 and 18b2 of the second insulating member 18. By doing so, displacement of the first insulating member 14a is prevented.

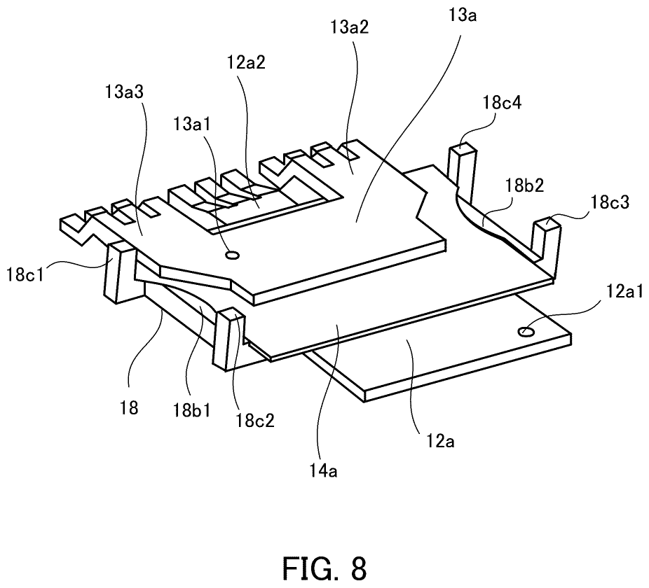

FIG. 8 depicts an example arrangement of a negative terminal. The negative terminal 13a is disposed on the front surface of the first insulating member 14a. As described earlier, the parts 13a2 and 13a3 extend from the front surface of the first insulating member 14a toward the inside of the case 11.

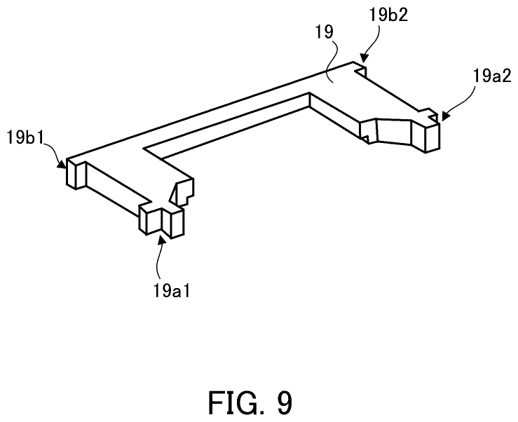

FIG. 9 is a perspective view depicting one example of a third insulating member. The third insulating member 19 is provided with fitting portions 19a1 and 19a2 into which the pillars 18c2 and 18c3 of the second insulating member 18 are fitted. By providing these fitting portions 19a1 and 19a2, it is possible to suppress displacement of the third insulating member 19 in the longitudinal direction of the case 11 and in an outward direction for the case 11.

The third insulating member 19 also includes protruding portions 19b1 and 19b2 that abut the pillars 18c1 and 18c4 of the second insulating member 18 in the longitudinal direction of the case 11. By providing these protruding portions 19b1 and 19b2, it is possible to further suppress displacement of the third insulating member 19 in the longitudinal direction of the case 11.

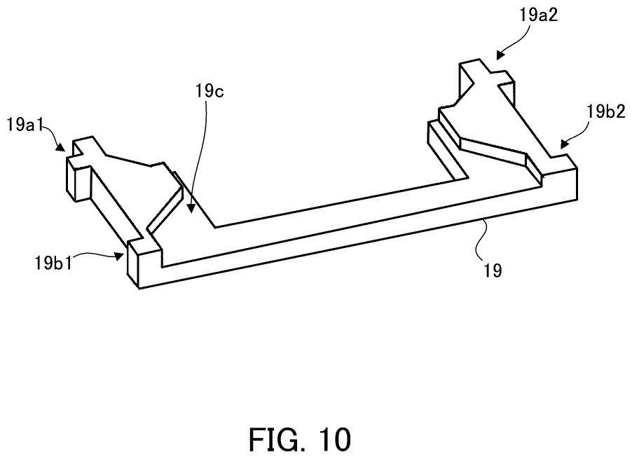

FIG. 10 is a perspective view depicting one example of a rear surface of the third insulating member. The rear surface of the third insulating member 19 (that is, the surface that faces the terminal structure 15a) is provided with a recess 19c into which the negative terminal 13a is fitted. This prevents displacement of the negative terminal 13a.

Note that although both the second insulating member 18 and the third insulating member 19 are respectively provided with the recesses 18a and 19c into which the positive terminal 12a and the negative terminal 13a are respectively fitted in the above example, the present disclosure is not limited to this. One of the second insulating member 18 and the third insulating member 19 may have a recess into which the positive terminal 12a or the negative terminal 13a is fitted.

Also, although the second insulating member 18 is provided with the first protruding portions 18b1 and 18b2 for positioning the first insulating member 14a in the example described above, the present disclosure is not limited to this. A surface of the third insulating member 19 that faces the terminal structure 15a (the rear surface depicted in FIG. 10) may be provided with a first protruding portion for positioning the first insulating member 14a.

Although the second insulating member 18 is provided with the pillars 18c1 to 18c4 and the third insulating member 19 is provided with the fitting portions 19a1 and 19a2 and the protruding portions 19b1 and 19b2 in the example described above, the present disclosure is not limited to this. The third insulating member 19 may be provided with pillars in the same way as the pillars 18c1 to 18c4, and the second insulating member 18 may be provided with fitting portions and protruding portions in the same way as the fitting portions 19a1 and 19a2 and the protruding portions 19b1 and 19b2.

### Modifications

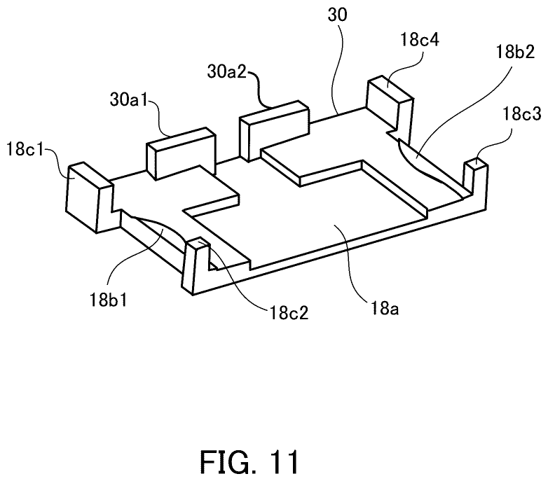

In FIGS. 11 to 17 described below, elements that are the same as those depicted in FIGS. 5 to 9 have been assigned the same reference numerals as those assigned to the elements depicted in FIGS. 5 to 9.

FIG. 11 is a perspective view depicting a modification to the second insulating member. In the same way as the second insulating member 18, a second insulating member 30 in the modification is provided with pillars 18c1 and 18c2 on a first side of the surface that faces the terminal structure 15a, and pillars 18c3 and 18c4 on a second side that is opposite to the first side. In addition, the second insulating member 30 of the modification is provided with second protruding portions 30a1, third side, which is positioned on an inside of the case 11, of the surface that faces the terminal structure 15a.

Parts of the second protruding portions 30a1 and 30a2 are provided on the recess 18a.

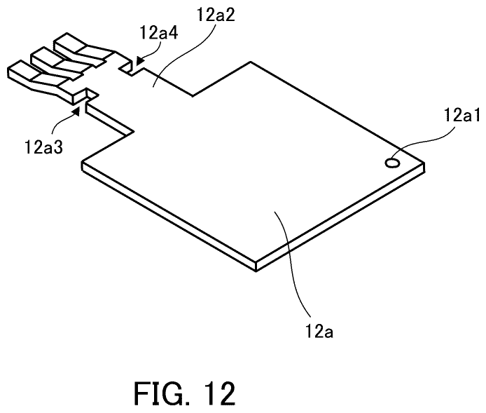

FIG. 12 is a perspective view depicting a modification to the positive terminal. The positive terminal 12a is provided with recesses 12a3 and 12a4 that fit together with the parts of the second protruding portions 30a1 and 30a2 depicted in FIG. 11 that are formed on the recess 18a of the second insulating member 30.

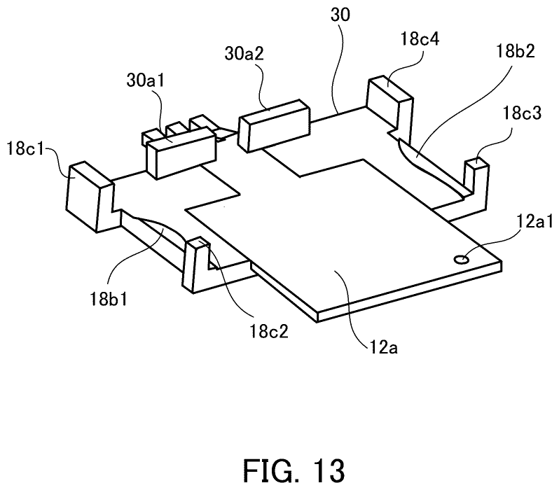

FIG. 13 depicts an example arrangement of a positive terminal on the second insulating member according to this modification. The positive terminal 12a is fitted into the recess 18a of the second insulating member 30. In addition, parts of the second protruding portions 30a1 and 30a2 are fitted into the recesses 12a3 and 12a4 of the positive terminal 12a as depicted in FIG. 12. By doing so, displacement of the positive terminal 12a is prevented.

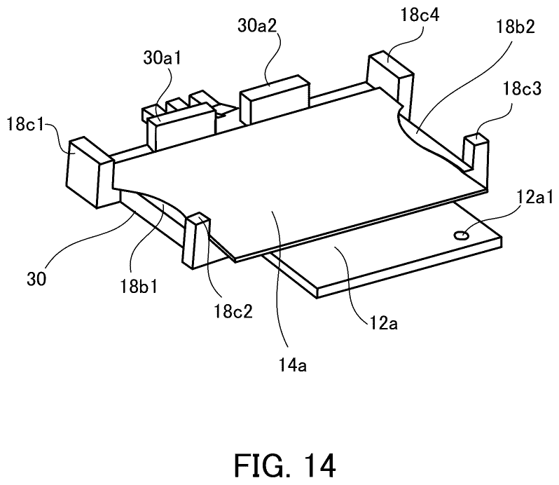

FIG. 14 depicts an example arrangement of the first insulating member on the second insulating member according to a modification. The first insulating member 14a is disposed on a part of the upper surface of the positive terminal 12a that is fitted into the recess 18a of the second insulating member 30. The first insulating member 14a is positioned by the first protruding portions 18b1 and 18b2 of the second insulating member 30. In addition, a side surface of the first insulating member 14a on the inside of the case 11 abuts the second protruding portions 30a1 and 30a2. This prevents displacement of the first insulating member 14a toward the inside of the case 11.

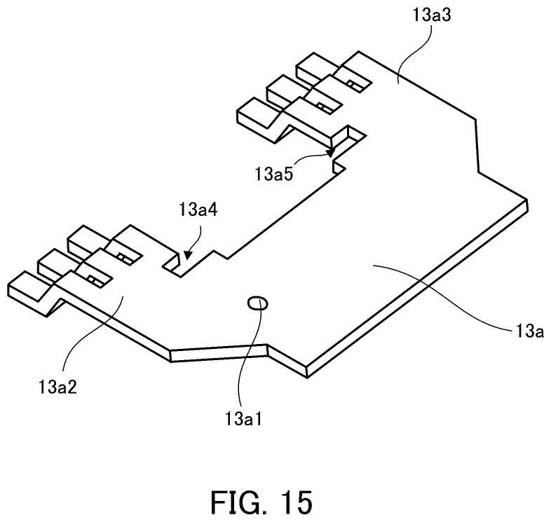

FIG. 15 is a perspective view depicting a modification to the negative terminal. The negative terminal 13a is provided with recesses 13a4 and 13a5 into which the second protruding portions 30a1 and 30a2 depicted in FIG. 11 are fitted.

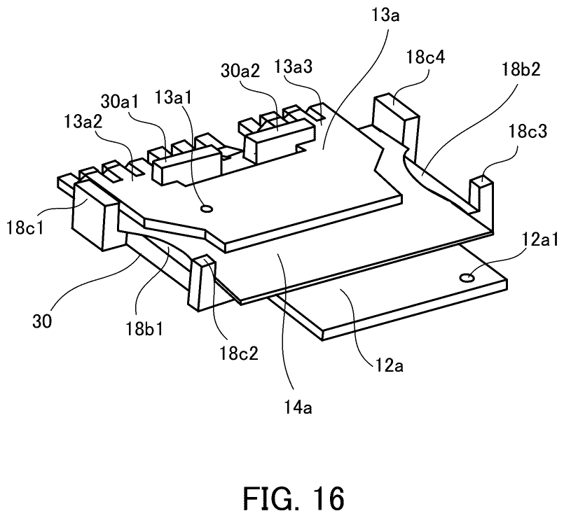

FIG. 16 depicts an example arrangement of the negative terminal when using the second insulating member according to the modification. The negative terminal 13a is disposed on the front surface of the first insulating member 14a. When the second insulating member 30 is used, the second protruding portions 30a1 and 30a2 are fitted into the recesses 13a4 and 13a5 of the negative terminal 13a as depicted in FIG. 15. This prevents displacement of the negative terminal 13a.

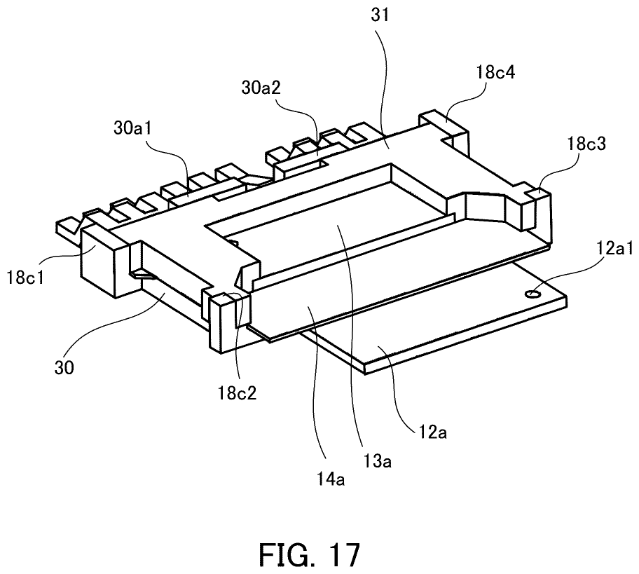

FIG. 17 depicts one example arrangement of a third insulating member when using the second insulating member according to the modification. Parts of a side surface of the third insulating member 31 abuts the second protruding portions 30a1 and 30a2. This prevents displacement of the third insulating member 31 toward the inside of the case 11.

Note that although the second insulating member 30 includes the second protruding portions 30a1 and 30a2 in the example described above, the third insulating member 31 may have second protruding portions in the same way as the second protruding portions 30a1 and 30a2. When this configuration is used, at least a part of a side surface of the second insulating member 30 abuts the second protruding portions provided on the third insulating member 31.

### Second Embodiment

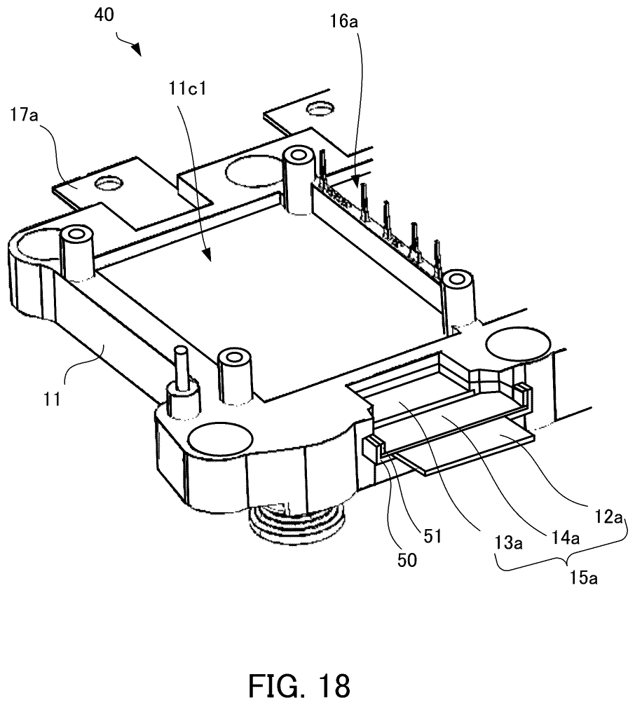

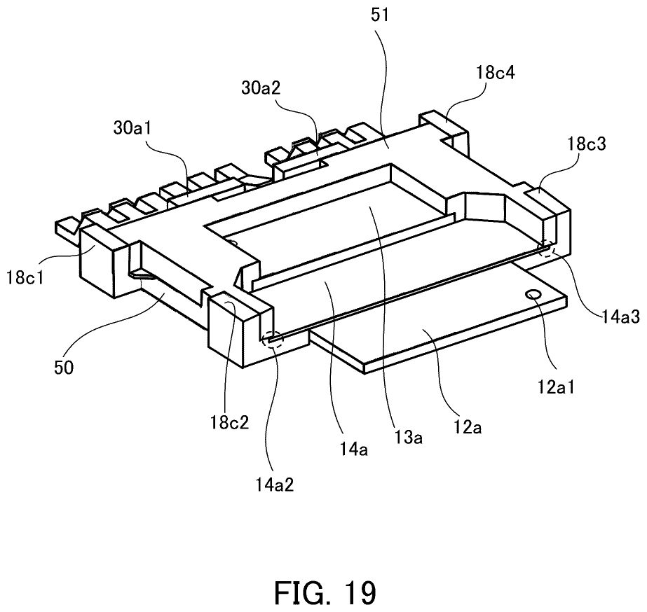

FIG. 18 is a perspective view depicting one example of a semiconductor module according to a second embodiment. FIG. 19 is a perspective view depicting one example of a terminal structure sandwiched between a second insulating member and a third insulating member. In FIGS. 18 and 19, elements that are the same as those depicted in FIG. 1 and FIG. 17 have been assigned the same reference numerals.

In the semiconductor module 10 according to the first embodiment described above, as depicted in FIG. 4, corners of the protruding portion 14a1 of the first insulating member 14a positioned toward the outside of the case 11 are not sandwiched between the second insulating member 18 and the third insulating member 19 and extend outside the case 11.

In contrast, in a semiconductor module 40 according to the second embodiment, ends 14a2 and 14a3 of a protruding portion of the first insulating member 14a positioned toward an outside of the case 11 extend outside the case 11 in a state where the ends 14a2 and 14a3 are covered by a second insulating member 50 and a third insulating member 51.

By doing so, it is possible to further suppress deformation of the protruding portion 14a1 of the first insulating 14a member and prevent deterioration in insulation performance.

Note that the second insulating member 50 in the example of FIG. 19 is provided with second protruding portions 30a1 and 30a2 as depicted in FIG. 11, however, the second protruding portions 30a1 and 30a2 may be eliminated as the second insulating member 18 depicted in FIG. 5.

Although aspects of a semiconductor module according to the present disclosure has been described above by way of the embodiments, the embodiments are mere examples and the present disclosure is not limited to the description given above.

As one example, the positive terminals 12a, 12b, and 12c may be connected as negative terminals to the negative electrode of the second switching element of the lower arm, and the negative terminals 13a, 13b, and 13c may be connected as positive terminals to the positive electrode of the first switching element of the upper arm. In other words, although the lower terminals of the terminal structures 15a, 15b, and 15c are described as being positive terminals and the upper terminals are described as being negative terminals in the example described above, positive and negative may be reversed.

According to the present disclosure, it is possible to suppress deformation of an insulating member that insulates a positive electrode and a negative electrode.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
a semiconductor unit including a first switching element and a second switching element respectively in an upper arm and a lower arm of the semiconductor unit;
a terminal structure including
a positive terminal that is electrically connected to a positive electrode of the first switching element,
a negative terminal that is electrically connected to a negative electrode of the second switching element,
a first insulating member that is sandwiched between the positive terminal and the negative terminal and includes a protruding portion where a part of the first insulating member protrudes from between the positive terminal and the negative terminal, and
a second insulating member and a third insulating member that sandwich the terminal structure from above and below and cover a front surface and a rear surface of at least a part of the protruding portion; and
a case that is integrally molded with the terminal structure which is sandwiched between the second insulating member and the third insulating member, and that houses the semiconductor unit.

2. The semiconductor module according to claim 1, wherein at least one of the second insulating member or the third insulating member has, in a surface thereof that faces the terminal structure, a recess in which the positive terminal or the negative terminal is fitted.

3. The semiconductor module according to claim 1,
wherein one of the second insulating member and the third insulating member has, on a surface thereof that faces the terminal structure, a first protruding portion for positioning the first insulating member.

4. The semiconductor module according to claim 1,
wherein one of the second insulating member and the third insulating member has, on a surface thereof that faces the terminal structure, a plurality of first protruding portions that are disposed facing a part of an outer edge of the first insulating member.

5. The semiconductor module according to claim 1, wherein
each of the second insulating member and the third insulating member has a surface that faces the terminal structure,
one of the second insulating member and the third insulating member has, on the surface, at least one pillar on each of a first side and a second side thereof, the first and second sides being opposite to each other, and
the other of the second insulating member and the third insulating member has a fitting portion that fits together with the pillars.

6. The semiconductor module according to claim 1, wherein
one of the second insulating member and the third insulating member has, on a surface that faces the terminal structure, at least one second protruding portions positioned on an inside of the case, and
the other of the second insulating member and the third insulating member has a side surface, at least a part of which is abutted by the at least one second protruding portion.

7. The semiconductor module according to claim 1,
wherein the protruding portion of the first insulating member has a plurality of corners, which are not sandwiched between the second insulating member and the third insulating member, and extend outside the case.

8. The semiconductor module according to claim 1,
wherein the protruding portion of the first insulating member has an end, which is covered by the second insulating member and the third insulating member, and extends outside the case.

9. The semiconductor module according to claim 1,
wherein a material of the case, the second insulating member, and the third insulating member is a thermoplastic resin.

10. The semiconductor module according to claim 1,
wherein the first insulating member is insulating paper.
